(19) United States
(12) Patent Application Publication
(10) Pub. No.: US 2011/0283934 A1
(43) Pub. Date: Nov. 24, 2011

(54) HIGHLY PRODUCTIVE APPARATUS FOR VACUUM COATING ROLL SUBSTRATES

(75) Inventors: Edgars Jadins, Jurmala (LV); Eduards Ausvalds, Riga (LV); Aivars Gaidlazda, Riga (LV)

(73) Assignee: SIDRABE INC., RIGA (LV)

(21) Appl. No.: 13/146,214

(22) PCT Filed: Feb. 1, 2010
(86) PCT No.: PCT/LV10/00001

§ 371 Date: Jul. 26, 2011

(30) Foreign Application Priority Data
Feb. 3, 2009 (LV) P-09-16

(51) Int. Cl. C23C 14/56

(52) U.S. Cl. 118/50

(57) ABSTRACT

Highly productive apparatus (1) for vacuum coating roll substrate (3) without touching any elements of the winding system by the substrate front surface and thereby preventing damage of the substrate front side and deposited coating. The apparatus comprises at least one loop winding device (9), which is installed between separate units (7) of the substrate cooling device. The said device comprises an input turning roller (11), central turning roller (12) and output turning roller (13), while each pair of neighboring turning rollers touches the substrate in a single plane. The suggested apparatus provides highly productive deposition of up-to-date high-technology coatings onto comparatively wide polymer films, metal foils and similar substrates. Necessary quality is provided, including for composite coatings. The possibility of processing fairly long roll materials provides uninterrupted operation of the deposition apparatus during long operation cycles, thus ensuring high productivity of the equipment.

The present invention relates to devices for vacuum coating roll substrates, mainly polymer films and metal foils of considerable width and length. In this field of technology the material length in a roll usually provides a fairly long continuous process in order to reach a highly effective output of the equipment. Machines for vacuum coating roll substrates are used quite broadly in various industries. They are traditionally widely used for the producing packaging and decorative materials and exploited more and more frequently in high-technology industries for the manufacturing various products for electronics, electrical engineering, communications facilities etc. In recent years intensive works have been carried out with the aim of working out solar energy converters on the basis of using such equipment. High technology industries bring forward more severe requirements to the deposited layers qualities, while the number of layers in the coating structure increases, the assortment of deposited materials expands. Often composition of these materials is very complicated and they are very sensitive to mechanical and thermal stress during vacuum processing. It is also very important to prevent damage of the substrate side to be coated (front side).

An apparatus for vacuum coating is known according to the Japanese laid-open application No 8325731 of TEIJIN LTD. The object of the known application is to prevent damage of the substrate front side and deposited coating. As FIG. 6 shows, the prior art apparatus (20) comprises an unwinding roll (21) of initial material (substrate), system of guide rollers (22), substrate (23), source of deposited material (26) and rewinding roll (27) of ready-made product. The system of the guide rollers is arranged so as to prevent the contact of the substrate front side (24) with the mentioned rollers during processing. Thereby damage of the substrate front side (24) is prevented, because there is no friction of this side against the surface of the rollers. It is particularly important if surfaces of the rollers are not ideal due to scuffing or imperfect finishing. It is also of importance that contact of the deposited coating with the rollers in the prior art apparatus is prevented. Alongside with that it should be noted that the prior art apparatus has a number of significant detriments.

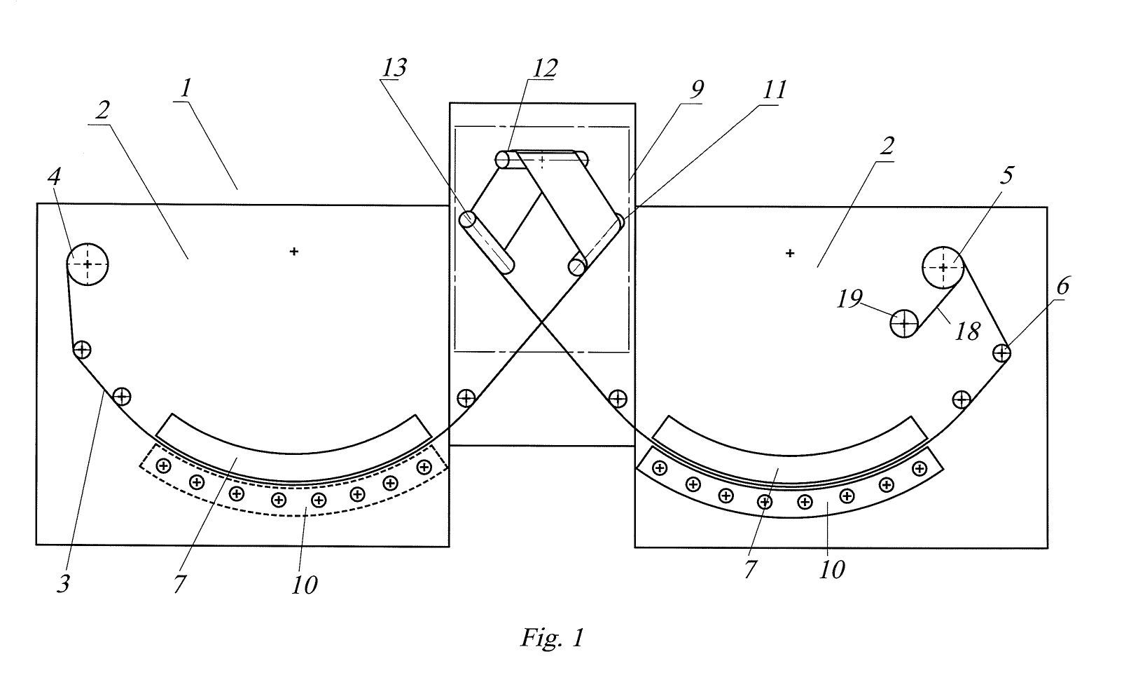

Firstly, it is of little use for highly productive systems, when efficient cooling of the substrate is necessary due to use of high-power deposition sources (magnetron sputtering devices, thermal evaporators etc) and/or processes of high intensity. Especially efficient cooling is necessary for coating very thin and/or exceedingly heat-sensitive substrates. However, specific arrangement of the guide rollers prevents sufficient contact of the substrate with a cooling unit (in this case—with a cooling drum). As it is shown in FIG. 1, maximal angle of the substrate contact with the drum is less than 180 degrees.

The possibility of the contact surface enlargement by increasing the drum diameter within the vacuum chamber is quite limited, because it requires enlargement of the vacuum chamber overall dimensions and use of additional powerful vacuum pumps, which lead to general appreciation of the equipment. Secondly, as it was already mentioned above, often it is necessary to deposit composite multi-component coatings for production of up-to-date high-technology materials. For producing multi-component coatings it is necessary to arrange two or more zones for depositing various layers of the coating within a single vacuum chamber in order to reach a fairly productive process. The arrangement of such zones in the prior art apparatus is unfeasible.

It is an object of this invention to increase the productivity of the deposition apparatus by using two or more deposition zones without contact of the substrate front surface with any elements of the winding system.

It is also an object of this invention to expand the technological capabilities of the apparatus for depositing various layers of the multi-component coating in different zones of the vacuum machine.

It is still another object of the invention to expand the technological capabilities of the equipment for coating thin long-length roll substrates of relatively large width—from 300 to 2000 mm.

The yield of vacuum machines for coating thin long-length roll substrates is usually limited, because such substrates and especially deposited multi-component coatings on them are subject to damages during the technological process.

It is necessary to enlarge the surface of the substrate contact with the cooling device working surface in order to increase the productivity.

That is why the set object is reached by the enlargement of the contact surface using two or more cooling units and a loop winding device between a pair of the cooling units. If necessary, the cooling device can contain more cooling units, in this case the loop winding device is installed between each pair of them. For the most part each cooling unit is manufactured in accordance with known art as a truncated circular segment. The segment radius is considerable in order to provide maximal surface of the substrate contact with the segment working surface. The cooling units can also be manufactured as cooling drums, whose use for cooling substrates is well known in the vacuum deposition technique. For any design of the cooling units their surface of contact with the substrate and consequently the cooling efficiency are limited by the substrate tension limit during its winding along the significant surface of contact. The force of the substrate and cooling surface contact is determined both by the substrate tension and the radius of the curvilinear cooling surface. The contact force goes down if the said curvilinear surface radius is increased. The applicant's practice testifies to the fact that an increase of the radius above 10 m has no positive effect. The offered design removes such limitation. The introduction of several cooling units provides expansion of the technological capabilities of the equipment, because it allows depositing separate layers of the multi-component coating in different zones, while the known principle of the substrate winding without contact of its front surface with the winding system elements is retained.

It is known that in case of increasing the width of thin roll substrates the risk of their damage during highly productive vacuum processing is increasing. Installation of the loop winding device between each pair of the cooling units provides enhancement of technological capabilities of the equipment owing to using comparatively wide (within the above-mentioned limits) roll substrates, because the said device together with the cooling units prevent buckling or another damage of the substrates.

FIG. 1 shows the preferred embodiment of the invention, where two cooling units in the form of truncated segments and one loop winding device are used.

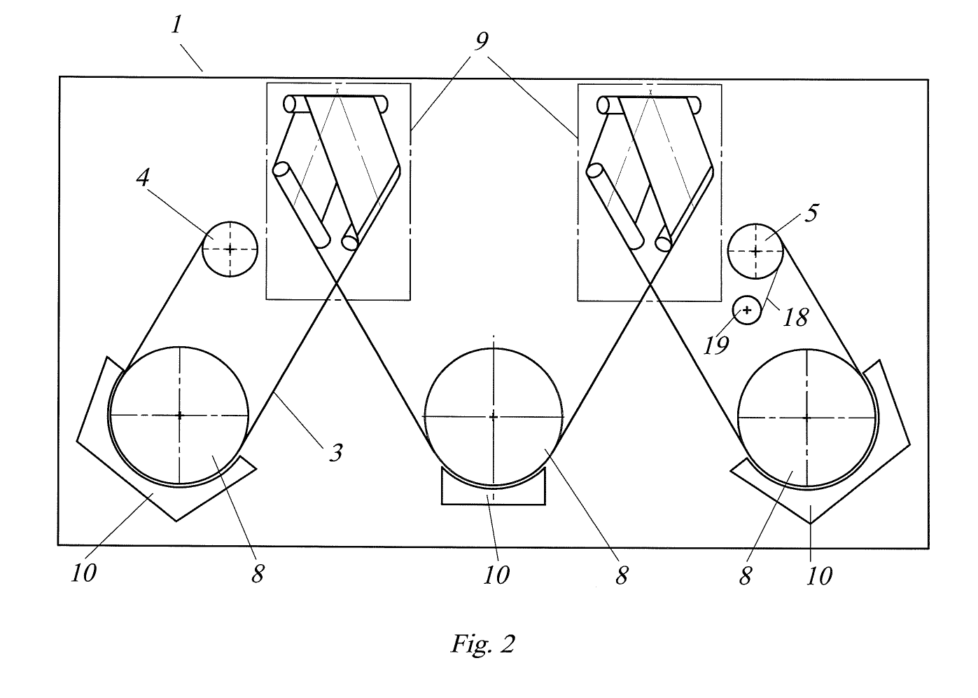

FIG. 2 shows the embodiment of the invention, where three cooling units in the form of drums and two loop winding devices are used.

FIG. 3a, 3b show the loop winding device.

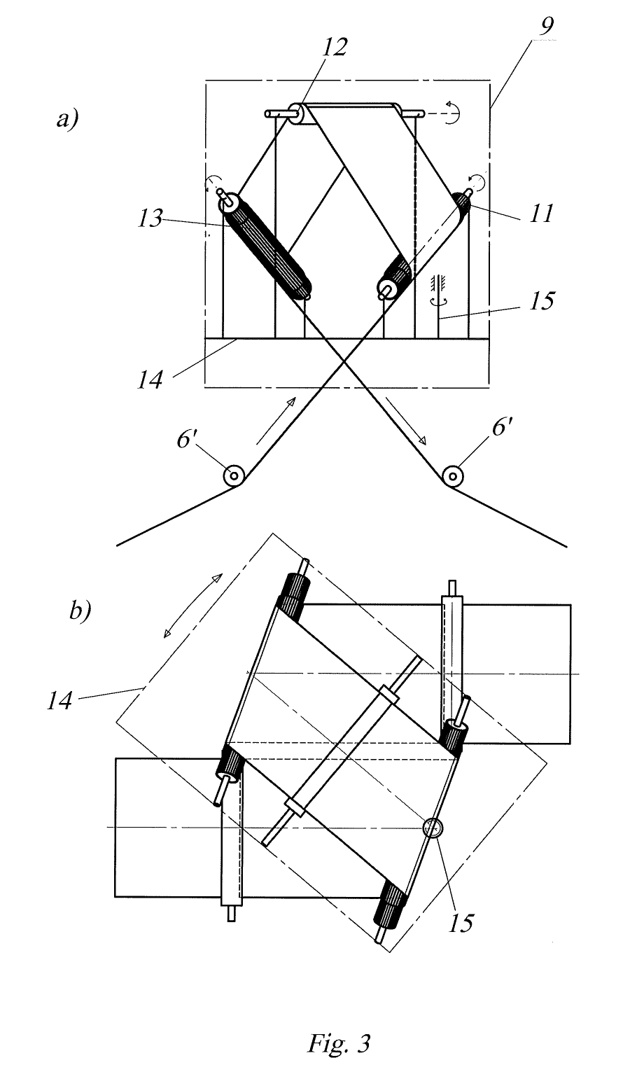

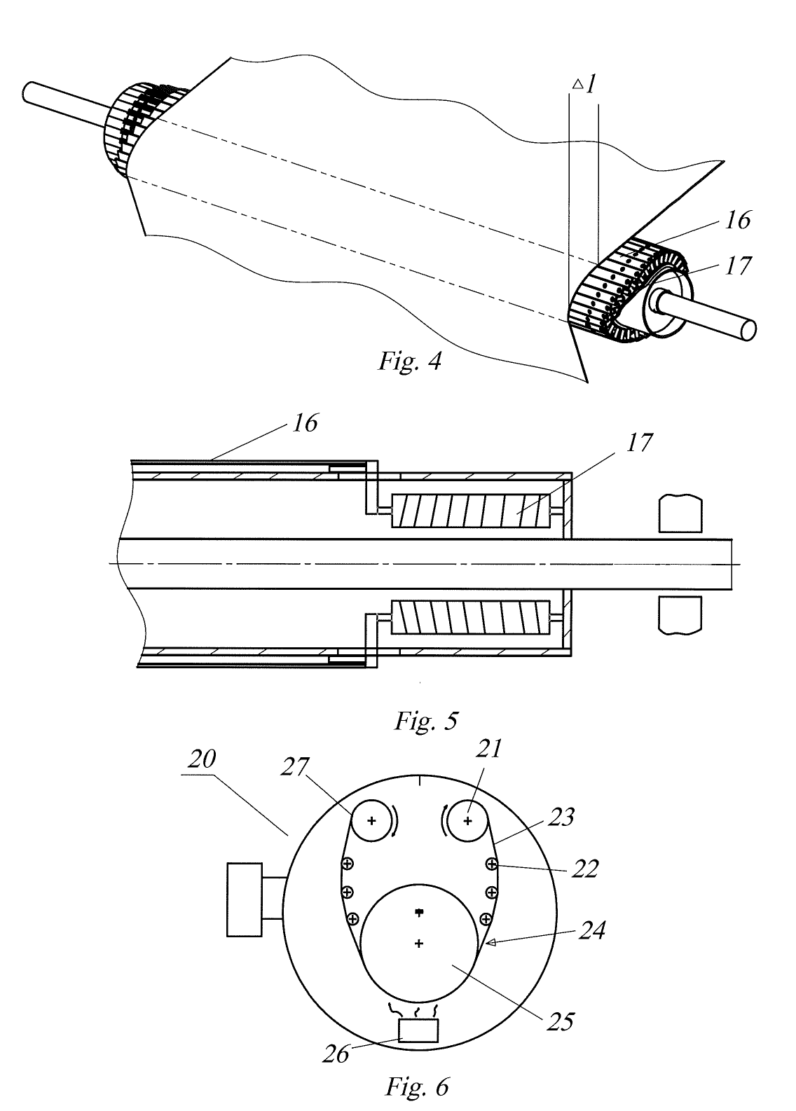

FIG. 4 shows a turning roller.

FIG. 5 shows a fragment of the turning roller and a device (17) of returning movable strips of the roller into the initial position.

FIG. 6 shows the prior art technical solution in accordance with the Japanese laid-open application 08325731, where the front side of the substrate does not come into contact with the guide rollers of the winding system.

A design of the highly productive apparatus (1), FIG. 1, for vacuum coating long-length roll substrates is suggested.

The apparatus comprises one or several deposition zones (2). The roll substrate (3) is wound from an unwinding roll (4) to a rewinding roll (5) along guide rollers (6) within the said deposition zones. Each deposition zone may be located in a separate vacuum chamber or in separate compartments of a common vacuum chamber. The device of the substrate cooling comprises two or several cooling units in the form of the truncated segment (pos. 7, FIG. 1) or the drum (pos. 8, FIG. 2), whose design is well known and widely used in this field of technique. The winding device comprises one or several loop winding devices (9) and each of them is installed between the cooling units.

FIG. 1 shows the embodiment of the invention with two cooling units in the form of the truncated segments of the diameter from 1 to 10 m, while the loop winding device (9) is installed between them.

FIG. 2 shows the embodiment of the invention with three cooling units in the form of the drums, while two loop winding devices (9) are installed between them. Depending on a deposited coating structure, substrate type and necessary productivity, the apparatus in accordance with the suggested invention can comprise more cooling units and loop winding devices, but the loop winding device is installed between each pair of the cooling units.

FIG. 3 shows the loop winding device, which comprises an input turning roller (11), a central turning roller (12) and an output turning roller (13). The winding system guide rollers (6′) next to the loop winding device are also shown. The guide rollers axes are perpendicular to the main direction of the substrate transportation from the unwinding roll to the rewinding roll.

FIG. 4 shows a possible design of the turning rollers (11) or (12). The design prevents sliding friction of the substrate on the surfaces of the mentioned rollers. Such effect is reached by the known method of equipping the outside surfaces of the rollers with movable strips (16) and a device (17) of the strips returning into the initial position.

The deposition apparatus in accordance with FIG. 1 is the preferred embodiment of the invention. It comprises two cooling units (7) in the form of the truncated segments, two deposition zones and one loop winding device (9). The suggested apparatus operates in the following way.

The substrate (3) is transported from the unwinding roll (4) along the guide rollers (6) and the curvilinear surface of the first cooling unit (7), where the substrate is coated with the deposition source (10). Known PVD sources (magnetron sputtering devices, thermal evaporators etc.), CVD, PECVD and other devices can be used as the deposition source. After depositing a layer (layers) of the coating onto the substrate on the first cooling unit the substrate is directed along the guide rollers (6) to the loop winding device (9), which is installed above the top level of the cooling unit in order to provide necessary tension of the substrate and its optimal contact with the curvilinear surface of the cooling unit. The guide roller (6′, FIG. 3a) and the input turning roller (11) are installed in a single plane and the axis of the input roller (11) is turned relative the main direction of the substrate transportation, as a result the substrate movement direction in the loop winding device is changed in accordance with the angle of turning of the input roller (11). The substrate is directed from the roller (11) to the central turning roller (12), whose axis is perpendicular relative the new direction of the substrate movement, which was set by the roller (11). At that the roller (12) is in a single plane with the roller (11).

The substrate turns around the roller (12) and comes to the output turning roller (13), whose axis is turned relative the main direction of the substrate transportation by the same angle as the axis of the roller (11), while the roller (13) is in a single plane with the roller (12) and the next guide roller (6′) of the winding system. While turning around the turning roller (13) the substrate changes the direction and again is moving along the main transportation direction with a certain transverse displacement, which is described below.

Thereby successive turning of the turning rollers angle-wise relative the main direction of the substrate movement and successive arrangement of the neighbouring rollers in a single plane provides desirable functioning of the loop winding device. It is also possible that there are no guide rollers between the loop winding device and the cooling unit, e.g. the drum. In this case the input and output turning rollers are in single planes with the corresponding cooling units.

In the process of the substrate travel through the loop winding device under the above described conditions the substrate loops without its front surface contact with a surface of any roller or other element of the winding system. The angle of turning of the rollers (11) and (13) and the distance between all rollers of the loop winding system are selected so that the transverse displacement of the main direction axis of the substrate winding would be equal to the substrate width+100 . . . 200 mm.

After turning the substrate arrives to the second cooling unit, where the next layer (layers) is (are) deposited, and then it is wound into the rewinding roll (ready-made product roll) (5).

It is useful to make a certain correction of the following path of the substrate transportation after its turning. It may be implemented with a centring device of a known design by mounting it between the loop winding device and the next cooling unit. In the preferred embodiment of the invention the centring device is integrated in the loop winding device, FIG. 3B). In response to a signal of an edge sensor (not shown) an actuating mechanism (not shown) provides a slight turning of a frame (14) and all turning rollers, which are mounted on this frame. In such a way the loop winding device corrects the substrate movement direction by a slight angle with simultaneous turning of the turning rollers around the centre (15).

As the invention is mainly intended for comparatively wide substrates (300 . . . 2000 mm), the substrate displacement along the turning roller axis is implemented without sliding along the roller surface, which is provided by one of known methods. In the preferred embodiment of the invention each outside surface of the roller comprises narrow strips (16), as shown in FIG. (4). The strips are easily movable over bearings (not shown) in axial direction.

The substrate is displaced in axial direction in tangency with the strips of the turning rollers surfaces and conveys the strips in the same direction by the distance, which is shown in FIG. (4). When the substrate exits from the tangency with the turning roller, the strips are released and return into the initial position by the device of returning (17). A spring or rubber tape may be used as basic components of the device of returning.

As the suggested apparatus provides depositing high-quality coatings without contact with the winding system rollers, in many cases a means is desirable for retention of the high qualities during the material rewinding into the ready-made product roll. It may be provided by known methods of the coating protection, e.g. using an interleaf, as FIG. 1 shows. The interleaf (18) is supplied from a roll (19) and wound together with the substrate into the ready-made product roll (5).

Thus the suggested apparatus provides highly productive coating comparatively wide polymer films, metal foils and similar substrates, while necessary quality is also provided for the composite coatings. The possibility of processing fairly long roll materials provides uninterrupted operation of the deposition apparatus during long operation cycles thus ensuring high productivity of the equipment.

1. A highly productive apparatus for vacuum coating roll substrates, comprising a deposition source, a substrate cooling device, a substrate winding system, whose elements are installed against the substrate side not to be coated, wherein the winding system comprises at least one loop winding device, which is installed between separate cooling units of the substrate cooling device, and loop winding device turning rollers having outside surfaces that are covered with axially movable strips.

2. The apparatus in accordance with claim 1, wherein the said loop winding device comprises an input turning roller, a central turning roller and an output turning roller, while each pair of neighbouring rollers touches the substrate in a single plane.

3. The apparatus in accordance with claim 2, wherein the neighbouring pair of the input turning roller and the corresponding guide roller of the winding system, as well as the neighbouring pair of the output turning roller and the corresponding guide roller of the winding system touch the substrate in a single plane.

4. The apparatus in accordance with claim 2, wherein the neighbouring pair of the input turning roller and the surface of the corresponding cooling unit, as well the neighbouring pair of the output turning roller and the surface of the corresponding cooling unit touch the substrate in a single plane.

5. The apparatus in accordance with claim 1, wherein the said loop winding device is installed above the top level of the corresponding cooling unit.

6. The apparatus in accordance with claim 1, wherein the said loop winding device is installed below the lower level of the corresponding cooling unit.

7. The apparatus in accordance with claim 1, wherein the said loop winding device is integrated with a centering device for the substrate.

8. The apparatus in accordance with claim 1, wherein the roll substrate is from 300 to 2000 mm wide.

9. The apparatus according to claim 1, wherein the said axially movable strips are equipped with devices of the strips return into initial positions outside the substrate touching zone.

10. The apparatus according to claim 9, wherein the said devices of the strips return into initial positions are made of springs.

11. The apparatus according to claim 9, wherein the said devices of the strips return into initial positions are made of rubber tapes.
